(19) United States
(12) Patent Application Publication
(10) Pub. No.: US 2010/0327370 A1
(43) Pub. Date: Dec. 30, 2010

(54) Non-planar embedded polysilicon resistor

(76) Inventors: Chia-Hong Jan, Portland, OR (US); Jeng-Ya Yeh, Portland, OR (US)

Correspondence Address: Winkle, PLLC;c/o CPA Global, P.O. Box 52050, Minneapolis, MN, 55402, US

(21) Appl. No.: 12/459,143

(22) Filed: Jun. 26, 2009

(51) Int. Cl. H01L 27/10; H01L 21/8234; H01L 21/02

(52) U.S. Cl. 257/380; 438/382; 257/E27.071; 257/E21.616; 257/E21.004

(57) ABSTRACT

The present invention discloses a method comprising: forming a sacrificial polysilicon gate (of a transistor) and a polysilicon resistor; and replacing said sacrificial polysilicon gate (of said transistor) with a metal gate while covering said polysilicon resistor.

### BACKGROUND OF THE INVENTION

1. Field of the Invention

The present invention relates to a field of semiconductor devices, and, more specifically, to a high-precision resistor and a method of fabricating the high-precision resistor.

2. Discussion of Related Art

Gate electrodes were initially formed from metal (aluminum). However, for many technology nodes, a Metal-Oxide-Semiconductor Field Effect Transistor (MOSFET) had included a gate electrode that was fabricated from polysilicon so as to permit ion implantation (to customize doping to N- or P-type in the same circuit) and silicidation (to reduce contact resistance). Consequently, a resistor associated with the MOSFET in a circuit was also fabricated with polysilicon. A so-called “gate-first” process sequence was universally practiced so as to permit blanket deposition of the polysilicon, plasma etch-defined gate lengths, lightly-doped tip regions, dielectric sidewall spacers, and self-aligned source/drain (to the gate electrode).

As dimensions of the MOSFET continued to be scaled down in recent technology nodes, polysilicon depletion became an increasingly severe problem. As a result, gate electrodes are now being formed from metal again. However, gate electrodes are no longer formed from aluminum. In order to achieve desired work functions, the gate electrodes are now usually formed from a transition metal, an alloy of transition metals, or a transition metal nitride.

However, adoption of the metal gate also provided advantages to an alternative so-called “gate-last” process. One implementation of the gate-last” process involved a so-called “replacement gate” process which allowed use of different metals for the N-FET and P-FET in the circuit.

When the material in the gate electrode was changed from polysilicon back to metal, the material in the resistor was also changed from polysilicon back to metal. Unfortunately, metal resistors often suffer from high process variability and a poor temperature coefficient.

Thus, it would be desirable to form the resistor with polysilicon again. However, such a change causes many challenges in process integration.

### BRIEF DESCRIPTION OF THE DRAWINGS

FIGS. 1-9 show cross-sectional views at different stages of fabrication of a device that includes a transistor and a polysilicon resistor according to an embodiment of the present invention.

### DETAILED DESCRIPTION OF THE PRESENT INVENTION

In the following description, numerous details, examples, and embodiments are set forth to provide a thorough understanding of the present invention. However, it will become clear and apparent to one of ordinary skill in the art that the invention is not limited to the details, examples, and embodiments set forth and that the invention may be practiced without some of the particular details, examples, and embodiments that are described. In other instances, one of ordinary skill in the art will further realize that certain details, examples, and embodiments that may be well-known have not been specifically described so as to avoid obscuring the present invention.

The present invention discloses a non-planar embedded polysilicon resistor and a method of fabricating the non-planar embedded polysilicon resistor.

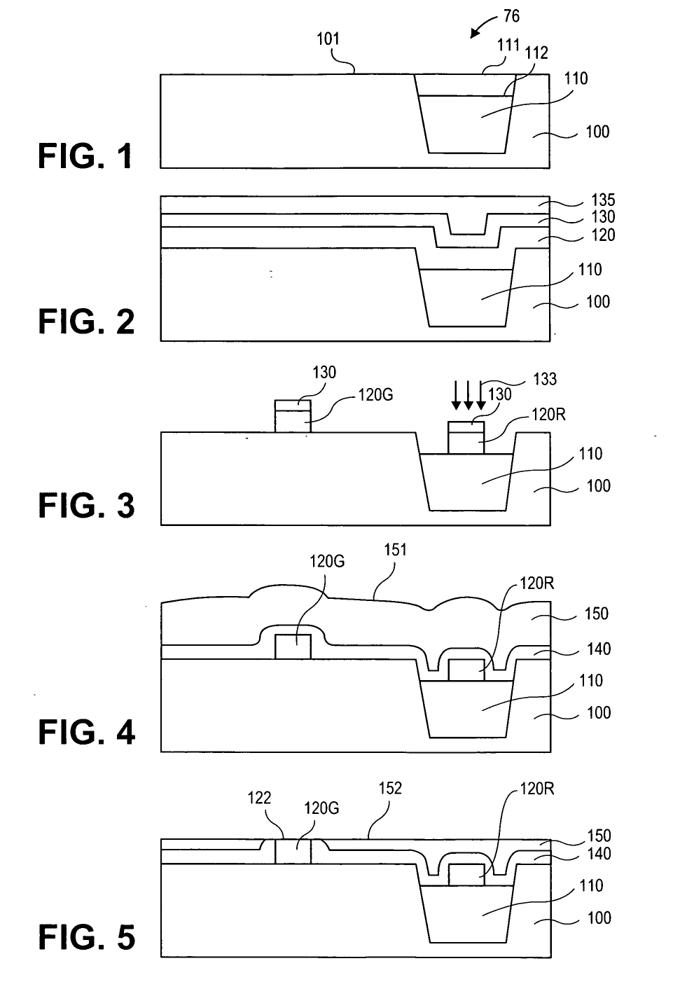

As shown in FIG. 1, a substrate 100 is provided that may comprise a bulk semiconductor, such as silicon, or a semiconductor-on-insulator (SOI).

An elongated opening, such as a trench, 76 is formed in the substrate 100. The trench may include a serpentine layout (not shown) in one or more horizontal planes.

The trench 76 is filled with a dielectric material 110, such as silicon oxide, silicon nitride, silicon oxynitride, nitrided silicon oxide, or carbon-doped oxide.

A planarization, such as a chemical mechanical polish (CMP), creates a top surface 111 of the dielectric 110 in the trench that is approximately level with a top surface 101 of the substrate 100.

An etch recesses the dielectric 110 in the trench and creates a new top surface 112 of the dielectric 110 in the trench that is now located lower than the top surface 101 of the substrate 100.

As shown in FIG. 2, a polysilicon layer 120 is formed over the dielectric 110 and the substrate 100.

A hard mask (HM) layer, such as silicon nitride, 130 is formed over the polysilicon layer 120.

A photoresist layer 135 is formed over the hard mask layer 130.

As shown in FIG. 3, photolithography in conjunction with deep ultraviolet (DUV) radiation is used to transfer a pattern from a photomask, or reticle, to form a photoresist mask 135.

An etch in conjunction with the photoresist mask 135 is used to further transfer the pattern into the underlying hard mask layer 130.

The photoresist layer is removed.

Another etch in conjunction with the hard mask layer 130 is used to still further transfer the pattern into the underlying polysilicon layer 120. A polysilicon resistor 120R is formed in the trench that is located correspondingly lower than a sacrificial gate 120G.

Photoresist patterning and ion implantation may be used to form lightly-doped regions to serve as self-aligned tip regions (adjacent to the sacrificial gate).

Another photoresist layer (not shown) may be formed and patterned with another photomask. The photoresist mask (not shown) in conjunction with ion implantation 133 is used to heavily dope the polysilicon resistor 120R.

The hard mask layer 130 remaining over the polysilicon is removed.

As shown in FIG. 4, a sidewall spacer layer 140 is formed over the gate 120G and the resistor 120R. The sidewall spacer may include one dielectric layer. Alternatively, the sidewall spacer may include two dielectric layers, such as in an “L”-shape (not shown).

Ion implantation is used to form heavily doped source and drain regions (self-aligned to he sidewall spacers).

Another dielectric layer 150 is formed over the sidewall spacer layer 140.

As shown in FIG. 5, another planarization, such as another CMP, removes most of the dielectric layer 150 and exposes a top surface 122 of the sacrificial gate 120G. However, the polysilicon resistor 120R remains embedded and thus protected by the remaining dielectric layer 150 and the sidewall spacer layer 140.

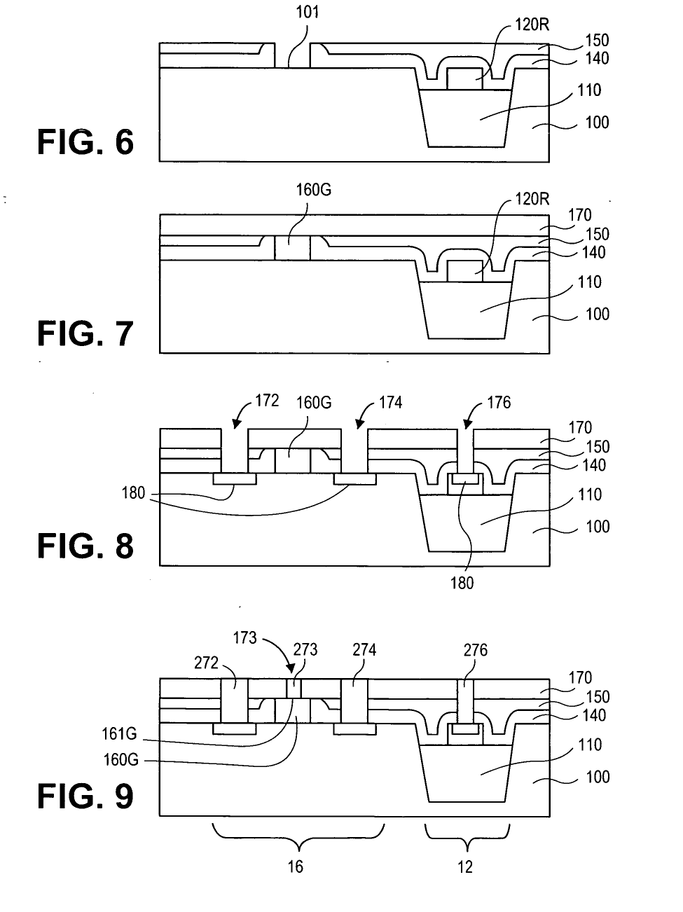

As shown in FIG. 6, another etch removes the sacrificial gate 120G to expose a top surface 101 of the substrate 100.

A thin high-k gate dielectric layer (not shown) is formed over the top surface 101 of the substrate 100.

Materials that may be used to form the thin high-k gate dielectric layer include: hafnium oxide, hafnium silicon oxide, lanthanum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate.

A capping layer of 1-5 monolayers of silicon or other material is formed over the thin high-k gate dielectric layer.

As shown in FIG. 7, a metal gate 160G is formed over the capping layer and the thin high-k gate dielectric layer.

Materials that may be used to form n-type metal include: hafnium, zirconium, titanium, tantalum, aluminum, and their alloys, such as, metal carbides that include these elements, such as, hafnium carbide, zirconium carbide, titanium carbide, tantalum carbide, and aluminum carbide. N-type metal layer may serve as a metal NMOS gate electrode with a workfunction of 3.9-4.2 eV. The remainder of the trench may be filled with a material that is easily polished, such as, tungsten, aluminum, titanium, or titanium nitride.

Materials that may be used to form p-type metal layer include: ruthenium, palladium, platinum, cobalt, nickel, and conductive metal oxides, such as, ruthenium oxide. P-type metal layer may serve as a metal PMOS gate electrode with a workfunction of 4.9-5.2 eV. The remainder of the trench may be filled with a material that is easily polished, such as, tungsten, aluminum, titanium, or titanium nitride.

A capping dielectric layer (not shown) is formed over the metal NMOS gate electrode and metal PMOS gate electrode.

Another dielectric layer 170 is formed over metal gate 160G and the remaining dielectric layer 150.

As shown in FIG. 8, a photoresist layer (not shown) is formed over the dielectric layer 170 and patterned with a photomask. The photoresist in conjunction with an etch through the dielectric layers 170, 150, 140 to form contact holes 172 (to the substrate 100 for the source), 174 (to the substrate 100 for the drain), and 176 (to the polysilicon 120 for the polysilicon resistor 120R).

A metal, such as nickel, is formed in the contact holes 172, 174, 176. Subsequent heat treatment forms a nickel silicide 180 at an interface between the nickel and the substrate 100 or the polysilicon 120 to reduce a contact resistance.

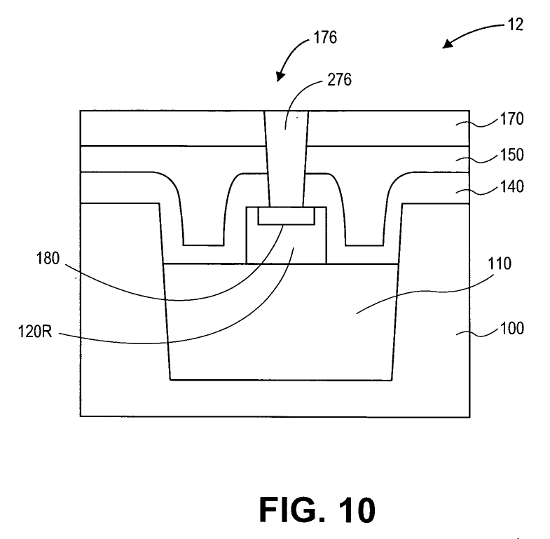

As shown in FIG. 9, a different photoresist layer (not shown) is formed over the dielectric layer 170 and patterned with a photomask. The photoresist in conjunction with an etch through the dielectric layer 170 to form a contact hole or opening 173 to expose a top surface 161G of the metal gate 160G of the transistor 16.

Another metal, such as copper, fills the contact holes or openings 172, 173, 174, 176 to form plugs or studs 272, 273, 274, 276 respectively.

More layers, such as 2-13 layers, of metals are formed over the device. The metal layers are separated by interlevel dielectric (ILD) layers formed from low-k dielectric materials, such as carbon doped oxides (CDO), that may include pores. The metal layers are connected by vias formed in the ILDs that are filled with metal.

A Damascene type process may be used. The Damascene type process may be single type or dual type. The dual type Damascene process may be via first type or trench first type.

As shown in FIGS. 9-10, an embodiment of the present invention also envisions a polysilicon resistor 12 that coexists with and is fabricated together with a high-k/metal gate transistor 16.

The polysilicon resistor 12 is non-planar since it is located on a dielectric layer 110 in a trench 76 in a substrate 100 (as shown in FIG. 1) that is recessed lower than a transistor 16 (as shown in FIG. 9).

The polysilicon resistor 12 is embedded, such as in a dielectric material. The polysilicon resistor 12 has a body that is formed from polysilicon 120R that has been ion implanted, such as with a high dose. The body of the resistor is contacted through a silicide 180 and a plug, or stud, formed from a contact 176 in the dielectric material 140, 150, 170 that is filled with a metal, such as copper.

Many embodiments and numerous details have been set forth above in order to provide a thorough understanding of the present invention. One skilled in the art will appreciate that many of the features in one embodiment are equally applicable to other embodiments. One skilled in the art will also appreciate the ability to make various equivalent substitutions for those specific materials, processes, dimensions, concentrations, etc. described herein. It is to be understood that the detailed description of the present invention should be taken as illustrative and not limiting, wherein the scope of the present invention should be determined by the claims that follow.

1. A method comprising:
forming a sacrificial polysilicon gate of a transistor and a polysilicon resistor;
replacing said sacrificial polysilicon gate with a metal gate while covering said polysilicon resistor; and
etching a first contact opening to said polysilicon resistor while covering said metal gate.

2. (canceled)

3. The method of claim 1 further comprising:
forming silicide in said first contact opening to said polysilicon resistor while covering said metal gate.

4. The method of claim 3 further comprising:
forming a second contact opening to said metal gate.

5. The method of claim 4 further comprising:
filling said first contact opening and said second contact opening with metal.

6. A device comprising:
a polysilicon resistor and a transistor with a metal gate, wherein said polysilicon resistor is embedded in a dielectric material.

7. (canceled)

8. The device of claim 6 wherein said transistor with a metal gate further comprises a high-k gate dielectric layer.

9. The device of claim 6 wherein said polysilicon resistor is ion implanted.

10. The device of claim 6 wherein said polysilicon resistor is located in a recessed dielectric layer in a trench.

11. The device of claim 6 wherein said polysilicon resistor is non-planar and located lower than said transistor.

12. (canceled)

13. (canceled)

14. (canceled)

15. (canceled)

16. (canceled)

17. The method of claim 1 wherein a high-k gate dielectric layer is formed below said metal gate.

18. The method of claim 1 wherein said polysilicon resistor is formed on a recessed dielectric layer in a trench.

19. The method of claim 1 wherein said polysilicon resistor is located lower than said sacrificial gate.

20. (canceled)

21. The method of claim 1 wherein said metal gate comprises a metal NMOS gate electrode.

22. The method of claim 1 wherein said metal gate comprises a metal PMOS gate electrode.

23. The device of claim 6 wherein said metal gate comprises a metal NMOS gate electrode.

24. The device of claim 6 wherein said metal gate comprises a metal PMOS gate electrode.
